(19) United States
(12) Patent Application Publication
(10) Pub. No.: US 2025/0046638 A1
(43) Pub. Date: Feb. 6, 2025

(54) JUNCTION PASSAGE CONTROL SYSTEM BASED ON LOCATION OF OHT USING POWER LINE COMMUNICATION

(71) Applicant: CANTOPS CO., LTD., Gyeonggi-do (KR)

(72) Inventors: Hak Seo OH, Gyeonggi-do (KR); Youl Kwon SUNG, Gyeonggi-do (KR); Sung Ik KIM, Gyeonggi-do (KR); Deok Ha LEE, Gyeonggi-do (KR); Yun Jung PARK, Gyeonggi-do (KR); Seong Min HWANG, Gyeonggi-do (KR); Won Jai LEE, Gyeonggi-do (KR); Sung Hyuk YOUN, Incheon (KR); Se Hun LEE, Gyeonggi-do (KR)

(21) Appl. No.: 18/787,006

(22) Filed: Jul. 29, 2024

(30) Foreign Application Priority Data
Aug. 3, 2023 (KR) 10-2023-0101444

(51) Int. Cl. H01L 21/677; H01L 21/67

(52) U.S. Cl. CPC H01L 21/67733; H01L 21/67259

(57) ABSTRACT

A junction passage control system based on a location of an OHT using a power line communication, includes: an OHT controller mounted on an OHT which moves along tracks; and a central controller that is installed in a junction section of the tracks and controls junction passing of a plurality of OHTs, wherein power lines are laid on the tracks in a zone from a start point of the junction section to an end point of the junction section, and the central controller and the OHT controller transmit and receive data for a junction passage control through power line communication to and from each other.

### BACKGROUND

The present invention relates to a technology for controlling passage in a junction section in an overhead hoist transport system, and more specifically, to a technology for enabling passage of OHTs in a junction section to be smoothly controlled without separate communication equipment, by enabling high-speed data processing to be performed for a device regardless of a fixed device or a moving device anywhere in the section in which a power line is laid.

An OHT (Overhead Hoist Transport) system is installed in large hospitals and production plants of semiconductors, LCDs, OLEDs, and solar panels where there are many objects to be transported. The OHT (Overhead Hoist Transport) system includes an OHT (Overhead Hoist Transfer) as a moving object for transporting the objects and rails for guiding the OHT. The OHT runs along the rails installed on the ceiling. The OHT is integrated and controlled by an OCS (OHT Control System), which issues transport orders. When the OHT (Overhead Hoist Transport) system is installed on LCD or OLED production lines, especially semiconductor production lines, the rails are placed using a ceiling space thereof in the clean room. In this case, the OHT, which is driven on the rails, conveys the objects such as LCDs, OLEDs, and semiconductor substrates between transport ports of processing or inspection devices. The running rails are supported from the ceiling of the clean room by pillars, etc., and consist of a running rail body and a power feeding rail. The OHT has a running drive unit that allows it to run along the running rail body, and a power receiving unit that receives signals from the power feeding rail and communicates with the OCS. In the OHT system, a plurality of OHTs convey the objects by running on the rails. The rails have a diverging section where the OHT diverges to allow it to move to another rail while running in a straight line, and a junction section that allows the OHT moving from the diverging section to enter another rail. Accordingly, the OHT diverges out to several locations and runs on a connected rail to transport the object to the desired location.

In such OHT system, a collision prevention system is sometimes provided to prevent the OHTs from colliding with each other at rail diverging section or rail junction section. As prior art, technologies have been proposed that recognize each other and prevent collisions by communicating between the OHTs through the guide path wire installed near the branching section or the junction section.

For example, Korean Patent Publication No. 10-2013-0120530 discloses a rail-guided transfer vehicle system including a generating unit configured to generate each of a plurality of signals each having different frequencies from the others, a transmitting unit configured to send each of the plurality of signals generated by the generating unit to the guide path wire, a receiving unit configured to receive each of the plurality of signals transmitted via the guide path wire, a determining unit configured to determine, based on the kind of the signal received by the receiving unit, whether the vehicle is slowed down, stopped, or kept travelling, and a controlling unit configured to control the vehicle in accordance with a result of a determination determined by the determining unit.

The above prior art should determine deceleration, stop, and running depending on the type of the frequencies received through the guide path wire, and remember which frequency signal is decelerating, stopping, or running depending on the type of frequencies received at each junction or diverging point. In situations where additional signals must be detected and processed, there is a possibility of conflicts due to errors in the complex configuration of the communication circuit (addition of frequency types) and memory management (definition of vehicle operation according to frequency type at each point).

Additionally, when simultaneous entry into the junction point occurs, a situation may occur in which both vehicles receive a stop signal and cannot drive together.

Additionally, there is a problem in that the response thereof is not possible in the junction section containing three or more multiple lines due to a limitation in the available frequencies.

### PATENT LITERATURES

Patent Literature 1: Korean Patent Publication No. 10-2013-0120530 (RAIL-GUIDED TRANSFER VEHICLE SYSTEM)
Patent Literature 2: Korean Patent Registration No. 10-1890847 (APPARATUS AND METHOD FOR CONTROLLING TRAFFIC LIGHT OF VEHICLE OF OVERHEAD HOIST TRANSFER)
Patent Literature 3: Japanese Patent Registration No. 5440701 (RAIL-GUIDED CART SYSTEM AND BRANCHING CONTROL METHOD FOR A RAIL-GUIDED CART SYSTEM)
Patent Literature 4: Japanese Patent Registration No. 4241306 (COLLISION PREVENTION CONTROL SYSTEM)
Patent Literature 5: Korean Patent Registration No. 10-2459085 (JUNCTION CONTROLLER FOR TRANSFER SYSTEM AND DRIVING METHOD THEREOF, AND TRANSFER SYSTEM)

### SUMMARY OF THE INVENTION

The invention is made to solve the above problem, and an object of the invention is to enable passage of OHTs in a junction section to be smoothly controlled without separate communication equipment, by enabling high-speed data processing to be performed for a device regardless of a fixed device or a moving device anywhere in the section in which a power line is laid.

According to an aspect of the invention to achieve the object described above, there is provided a junction passage control system based on a location of an OHT using a power line communication, including: an OHT controller mounted on an OHT which moves along tracks; and a central controller that is installed in a junction section of the tracks and controls junction passing of a plurality of OHTs, wherein power lines are laid on the tracks in a zone from a start point of the junction section to an end point of the junction section, and the central controller and the OHT controller transmit and receive data for a junction passage control through power line communication to and from each other.

Here, the central controller determines a location of a danger zone start point and a danger zone end point on each of the tracks of the junction section and, based on the determined locations, controls passage of the OHTs through the junction section.

In addition, the OHT controller transmits, to the central controller through power line communication, OHT identification information and traveling information including at least one or more of OHT information indicating a traveling or stopping status, a travel distance, and a travel speed.

In addition, the central controller transmits, to the OHT controller through the power line communication, data about the danger zone start point, information indicating whether access is permitted, the selected OHT identification information, and information of the number of OHT controllers in communication.

In addition, the junction passage control system further includes a termination device that includes a transmission line matching unit for stable communication between the central controller and the OHT controller, the transmission line matching unit being installed at a terminal end of the power line, and that is coupled with the power line via a contact coupler to perform the power line communication with the central controller.

In addition, the central controller is coupled with the power line via a contact coupler; and the OHT controller is coupled with the power line via a non-contact coupler to perform the power line communication with the central controller.

In addition, a junction section status display device that displays a status of the junction section is installed at the start point of to the junction section of the tracks; and a camera is installed on each of the OHTs, and the OHT controller acquires access availability status information of the junction section from an image captured by the camera.

In addition, each of the OHTs includes a sensor for detecting location movement information, and the OHT controller transmits the location movement information detected by the sensor to the central controller.

In addition, the sensor is any one of an optical flow sensor, an IMU sensor, or a camera that detects a change on a surface of each of the tracks and recognizes a change of a location.

In addition, a location information update device for detecting location movement information of the OHTs is installed on each of the tracks in the junction section, and the OHT controller receives the location movement information of the OHTs through a non-contact power line communication from the location information update device; and a frequency of the non-contact power line communication is different from a frequency of communication between the central controller and the OHT controller.

In addition, the power line is a two-wire transmission line and is laid so that a distance between two conductor lines is periodically variable; and the OHT controller calculates a traveling location of each of the OHTs based on a reception intensity of a signal received through the power line.

### BRIEF DESCRIPTION OF THE DRAWINGS

The above and other objects, features and advantages of the present invention will be more apparent from the following detailed description taken in confluence with the accompanying drawings, in which:

FIG. 1 illustrates a configuration in which an interface medium for communication is installed on a track according to an embodiment of the invention;

FIG. 2 illustrates a configuration in which interface mediums for communication are installed on tracks according to another embodiment of the invention;

FIG. 3 is a configuration diagram of the power communication line according to the invention;

FIG. 4 is a system configuration diagram for illustrating non-contact power communication performed in OHTs;

FIG. 5 is a diagram illustrating a method of recognizing a location of a moving object depending on a transmission line wiring configuration;

FIG. 6 illustrates a configuration of a junction control system employing a technique of obtaining the location movement information of the OHT by mounting a sensor on the OHT; and

FIG. 7 illustrates a configuration of the junction control system with the location information update device installed on the track.

### REFERENCE SIGNS LIST

10: power supply device
20: OHT controller
30: central controller
40: termination/extension device
51 and 52: location information update device
60: junction status display device
21, 31, and 41: power
22, 32, and 42: power line communication unit
23: camera
24: loop antenna
25, 35, and 45: coupler
26: sensor
27: power line communication unit

### DETAILED DESCRIPTION OF THE PREFERRED EMBODIMENT

Since the description of the present invention is a mere embodiment for structural and functional description, it must not be interpreted that the scope of the present invention is limited by the embodiments described in the text. That is, since the embodiments can be variously changed and have various forms, it should be understood that the scope of the invention includes the equivalents for realizing the technical concept. Also, since the specific embodiments do not include all objects and effects presented by the present invention, the scope of the present invention is not limited by them.

Unless differently defined, all the terms used here including technical or scientific terms have the same meaning with what is generally understood by one who has common knowledge in the technical field that this invention belongs to. The terms such as those defined in the dictionary commonly used will be interpreted to have the meanings matching with the meanings in the context of the related technologies. Unless clearly defined in this application, they are not interpreted as ideal or excessively formal meanings.

Hereinafter, a preferred embodiment according to the invention will be described in detail with reference to the accompanying drawings.

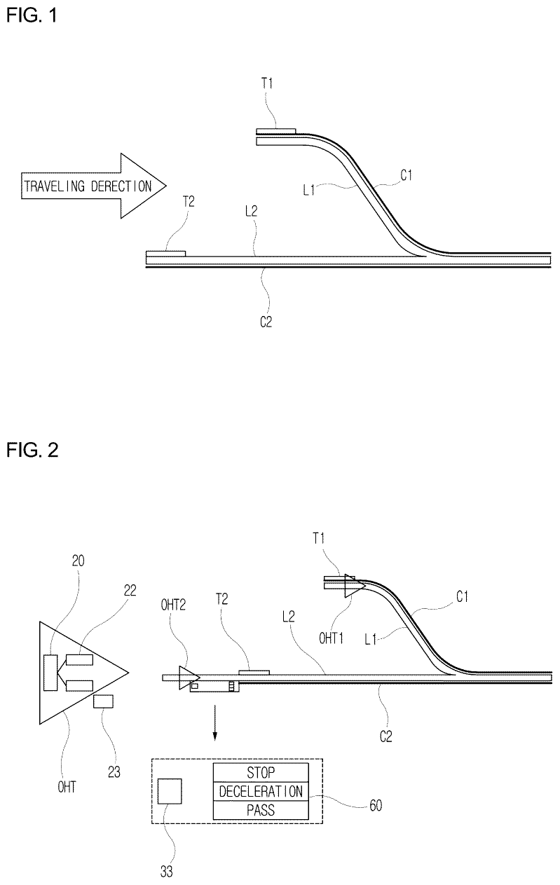

FIG. 1 illustrates a configuration in which an interface medium for communication is installed on a track according to an embodiment of the invention.

A junction section having a configuration in which two tracks merge to one track is exemplified in the following embodiments, but the invention is not limited thereto, and it is needless to say that the invention is applicable to a junction section including more tracks.

As illustrated in FIG. 1, in the invention, interface mediums (C1 and C2) are installed on tracks (L1 and L2) on which an OHT travels, respectively, so that communication can be performed between a central controller (30) and the OHT controller (20) to be described below.

The interface mediums (C1 and C2) are installed on the tracks (L1 and L2), on which the OHT travels, from an entrance that the OHT accesses to an end of the junction section in order to prevent an unnecessary slowdown or a traveling stoppage that can occur due to a junction passage sequence of the OHT.

In the invention, a power line having a shape of a transmission line is used as the interface mediums (C1 and C2), and power input specifications and a power input status can vary depending on a configuration of additional optional functions.

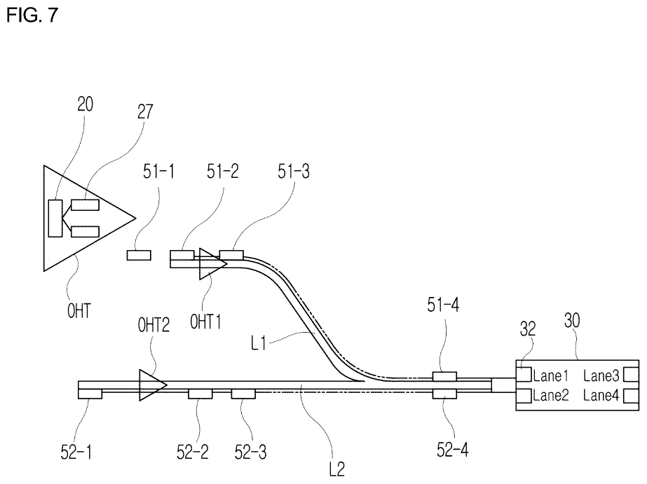

The case where power is input may employ a configuration for a case where power needs to be applied to a separate sensor (location information update device, refer to the description of FIG. 7) installed on the tracks in the junction section among methods for acquiring the location movement information of the OHT.

FIG. 2 illustrates a configuration in which interface mediums for communication are installed on tracks according to another embodiment of the invention.

In the embodiment illustrated in FIG. 2, in a high travel section of the OHT or an adjacent junction section thereto, a junction status display device (60) is installed at an entrance that the OHT accesses, and access availability status information of an access portion can be acquired even from a long distance by a camera (23) attached to the OHT.

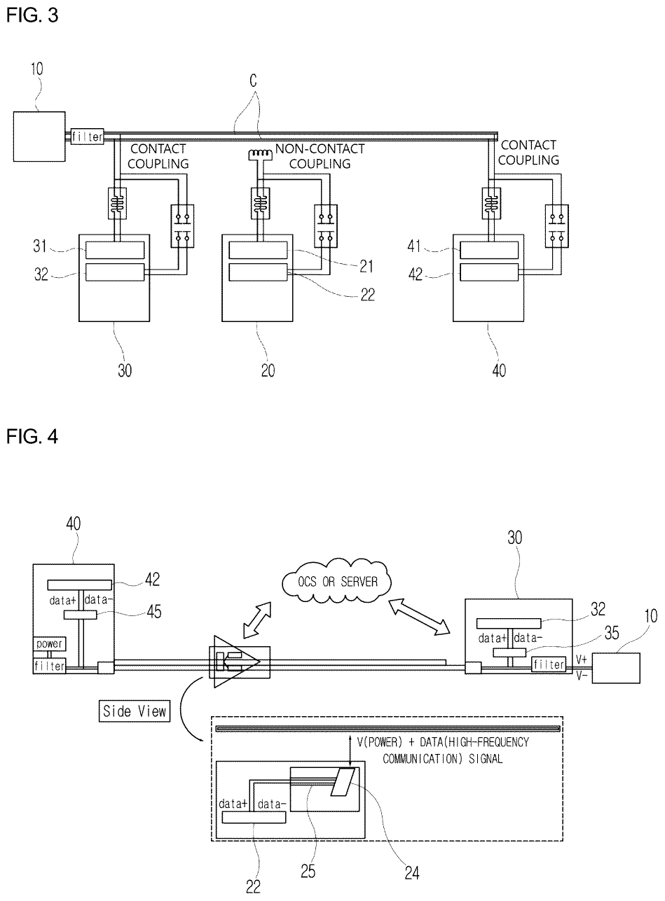

FIG. 3 is a configuration diagram of the power line communication according to the invention, and FIG. 4 is a system configuration diagram for illustrating non-contact power line communication performed in OHTs.

Prior to the description of FIG. 3, the power line communication is to be briefly described.

The power line communication (PLC) is a technology that performs communication by transmitting data (voice, video, or the like) in a signal having a high frequency from hundreds of KHz to tens of MHz through a power line as a medium that supplies alternating current or DC power.

In recent years, the power line communication generally has a frequency range extended to 30 MHz, and advances in the digital signal processing technology enables high-speed communication from a few Mops to hundreds of Mops or more to be performed. If this power line communication technology is used in the increasingly complex logistics automation field, this technology will be effective in transmission processing of a large volume of data while minimizing wiring. High-speed control signal transmission needs to be performed even in a junction in which fast moving OHTs converge. In order to transmit a large volume of data from a sensor, a camera, or the like and a high-speed control signal of the junction from the central controller at once, a system that processes a large volume of data at a high speed is even more required.

With reference to FIG. 3, the invention includes a non-contact power line communication configuration using a non-contact coupler as well as a contact power line communication since non-contact communication with the OHT accessing the junction is necessary.

In other words, in the invention, a coupling method using a contact coupler is used for a central controller (30) and a termination/extension device (40) physically connected to a power line (C) as illustrated in FIG. 3. In the contact power line communication, the central controller (30) and the termination/extension device (40) are physically connected to a power line laid using the contact couplers (35 and 45).

Power is supplied from a power supply device (10) to the central controller (30) and the termination/extension device (40) through the power line (C) physically connected thereto, and transmission of a high-frequency communication signal is also performed between the central controller (30) and the termination/extension device (40) to each other through the power line (C) and communication therebetween is performed.

A method using non-contact couplers (24 and 25) is used for a device that is difficult to physically connect, such as the OHT.

The power line (C) to be laid will become a transmission line in a form in which an induced magnetic field can be generated, and the power line will be able to operate like a near-field antenna to be coupled with a surrounding near-field antenna via a magnetic field.

In the invention, the power line (C) connected to the central controller (30) is configured as a transmission line by using the above principle and has a configuration as illustrated in FIG. 4 in which a roof antenna that is a near-field antenna is connected to the OHT controller such that magnetic field coupling with each other can be performed.

With reference to FIG. 4, a non-contact coupler installed in the OHT can include a loop antenna (24) that receives power generated from a power line which is a two-wire transmission line and a wireless power signal combined with high-frequency data, and a coupler (25) which filters the high-frequency data and provide it to a power line communication unit (22). Moreover, a power supply for driving the OHT controller (20) can include an internal power supply separately.

The central controller (30) is a collision preventing central controller installed in the junction of the tracks, can be connected to an OCS (or a high-rank server) through wired/wireless communication, and is configured to be able to receive information necessary for junction passage control in real time or remotely control functional improvement or the like of the central controller (30). The central controller (30) generates a traffic control sequence such that simultaneous access of the OHTs can be fundamentally prevented.

The OHT controller (20) is a device that is mounted on the OHT that accesses the junction and can perform power line communication with the central controller (30). In the following embodiment, a concept in which a control unit that controls the OHT and communication means for performing the power line communication with the central controller (30) are integrated are described, but are not limited thereto, and the control unit that controls the OHT through the OCS and a power line communication unit can be separated in a structure in which the control unit and the power line communication unit are connected via an I/O or communication device.

The OHT controller (20) includes a junction passage sequence controlled by the central controller (30) for access to the junction, and the OHT controller (20) can also include a configuration in which a travel distance (location movement information) can be known when the OHT moves on the track.

The location movement information can be acquired using a sensor installed in a moving OHT (refer to the description of FIG. 6), or can be received as input through a separate sensor installed on the junction track where the moving OHT travels (refer to the description of FIG. 7).

The termination/extension device (40) includes a transmission line matching unit for stable communication between the central controller (30) and the OHT controller (20), the transmission line matching unit being installed at a terminal end of the power line (C). The termination/extension device (40) is coupled with the power line (C) via a contact coupler (45) to perform the power line communication with the central controller (30).

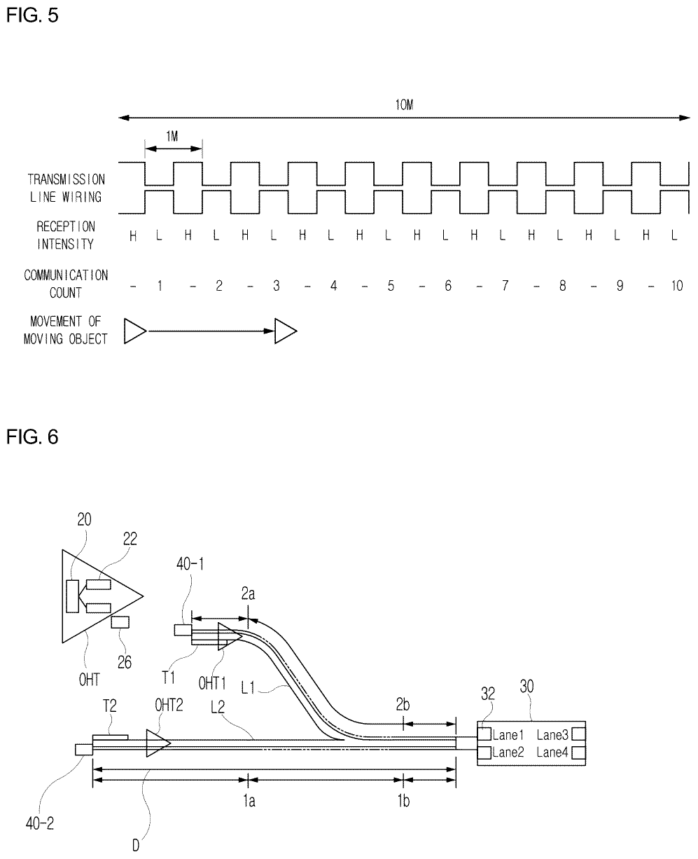

FIG. 5 is a diagram illustrating a method of recognizing a location of a moving object depending on a transmission line wiring configuration.

The embodiment illustrated in FIG. 5 is configured to enable the OHT controller (20) to detect the location movement information of the OHT on the basis of the signal intensity received in a process of communication with the central controller (30) according to a wiring structure of two power lines (two-wire transmission line).

In the two-wire transmission line, an impedance mismatch occurs due to a change in characteristic impedance (Z) depending on a distance, a shape, or the like of two conductors. Hence, standing waves are generated in the two-wire transmission line, and the communication signal intensity is changed due to these standing waves. This change in intensity affects communication performance.

In a case where terminal ends are aligned, the communication signal intensity is constant in the two-wire transmission line in which two conductors have a constant distance, that is, are parallel, except for a communication dead zone caused by a predictable electrical characteristic and a structural problem of the transmission line. However, if the distance between the two conductors is not constant, that is, if the two conductors are not parallel or different in shape, the standing waves are generated depending on each location in the two-wire transmission line, and the communication signal intensity changes.

This embodiment includes a configuration in which a location of a moving object can be identified using a change in communication signal intensity which occurs depending on a distance between the two-wire transmission lines and a shape of the transmission lines.

As illustrated in FIG. 5, the two conductors can be arranged to have periodically repeated narrow or wide distances so that the communication signal intensity is variable.

Reception is performed with low reception sensitivity at a position where the communication signal intensity is weak, and reception is performed with high reception sensitivity at a position where the communication signal intensity is strong.

A traveling location can be calculated using the communication intensity received while the OHT travels on the transmission line.

As an example of implementation, in a case where the transmission line is 10 m in length, it is possible to count 10 times at 1 m intervals using the received communication intensity when the transmission line is disposed at 1 m intervals as illustrated in FIG. 5.

For example, if the communication counter of an OHT is three times, the current location of the moving object is a location of 3 M from a start point of access.

FIG. 6 illustrates a configuration of a junction passage control system employing a technique of obtaining the location movement information of the OHT by mounting a sensor on the OHT.

In the junction passage control system of FIG. 6, a separate sensor (26) such as an optical flow sensor is added to the OHT controller (20) so that the location movement information of the OHT can be obtained from the OHT controller (20) when the OHT is moved.

Sensors installed on the OHT can include any configuration in which a change in location movement can be recognized, such as an optical flow sensor, an IMU sensor, or a camera that recognizes a change in location by detecting a change in surface of the track on which the OHT travels.

The OHT controller (20) transmits, to the central controller (30), a travel distance (ta), a travel speed, an OHT number, and OHT status (traveling/stopping) information based on station tags (T1 and T2).

The central controller (30) transmits, to the OHT controller (20), locations of danger zone start point (1a and 2a) for each of the tracks (L1 and L2), an access permission status between the danger zone start points (1a and 2a) of and danger zone end points (1b and 2b), and control status information for each of the OHT controllers.

Here, the central controller (30) calculates a location (D−α) of the OHT by reflecting an a value and a travel speed based on a total length (D) of each track.

The central controller (30) successively calculates locations of the OHTs and transmits an access permission signal for allowing an OHT close to the danger zone start point (1a or 2a) to first access the start point on the basis of the calculated locations of the OHTs, to the OHT controller (20) of the OHT.

Incidentally, the OHT having a travel speed of ‘0’ is considered in the stoppage and working (unloading/loading) and is excluded from access permission targets.

The central controller allows only one OHT to access between the danger zone start points (1a and 2a) and the danger zone end points (1b and 2b). An OHT (OHT1) on a first track (L1) of the OHTs located on the two tracks is located closer to the danger zone start point (1a or 2a) than a OHT (OHT2) on a second track (L2) is in FIG. 6, so the access permission signal is transmitted to the OHT controller (20) of the OHT (OHT1) on the first track (L1).

The OHT controller (20) tries to access the junction section only in the case of receiving the access permission signal from the central controller (30), and the OHT controller stops at a location of the danger zone start point (1a or 2a) in a case where the access permission signal is not received from the central controller (30) in the junction section.

In a case where the central controller determines that a location of the OHT (OHT1) that has first accessed the junction section has passed the danger zone end point (1b or 2b), the central controller transmits the access permission signal to an OHT close to the danger zone start point (1a or 2a) on the basis of locations of the rest of OHTs that intend to access the junction section so that the OHT can access the junction point.

Table 1 below shows a communication packet that is data transmitted from the OHT controller (20) of the OHT intending to pass the junction section to the central controller (30), and includes OHT information indicating the traveling or stoppage status, traveling information such as a travel distance and a travel speed, and ID information. When the central controller (30) calls the OHT controller (20), a target respondent OHT transmits the following data as a response signal.

TABLE 1

| | Traveling | |
|---|---|---|
| OHT information | information | ID |
| Traveling/Stoppage | Travel distance, | OHT identification |
| | travel speed | number |

Table 2 below shows a traffic control packet structure of data transmitted in a broadcast form from the central controller (30) to the OHT controller (20) in communication. In Table 2 below, presence is recorded in the permission for access in a case where there is an OHT permitted to access the junction section, and absence is recorded in the case of no OHT, and the number of OHT controller N slots may vary depending on the number of OHT controllers in communication. The control information includes an OHT number and OHT control information (access/stopping) received from the OHT controller.

TABLE 2

| | OHT | OHT | | OHT |
|---|---|---|---|---|
| Track information | controller 1 | controller 2 | . . . | controller N |
| Danger zone start | Control | Control | . . . | Control |
| point, permission | signal | signal | | signal |
| for access, | | | | |
| respondent OHT | | | | |
| identification, | | | | |
| Number of OHT | | | | |
| controllers in | | | | |
| communication | | | | |

FIG. 7 illustrates a configuration of the junction passage control system with the location information update device installed on the track.

The control system in FIG. 7 enables the OHT controller to update the location movement information by installing location information update devices (51 and 52) on the junction tracks on which the OHTs travel.

A plurality of location information update devices is installed on the first track (L1) and the second track (L2). FIG. 7 illustrates an example in which safe zones of the first track (L1) and the second track (L2) have respective sets of two location information update devices (51-1 and 51-2, and 52-1 and 52-2), one device (51-3 or 52-3) is installed at a boundary point between the safe zone and the danger zone, and one device (51-4 or 52-4) is installed at the terminal end side of the danger zone.

As described above, the sensor (location information update device) installed on the junction track can include a configuration in which the tracks on which the OHTs move are laid by dividing the tracks into a safe region and a danger region, and information of the safety region and danger region is transmitted to the OHT controller (20) on the accessing OHT so that the location information can be known.

The OHT controller (20) includes a power line communication unit that can simultaneously perform transmission and reception at different communication frequencies from each other. In this embodiment, communication between a power line communication unit (27) and the location information update devices (51 and 52) is performed to transmit and receive location information at a communication frequency (F2) different from a communication frequency (F1) between the OHT controller (20) and the central controller (30).

In a case where the OHT is located in a region between a first location information update devices (51-1 or 51-2) and a third location information update devices (51-3 or 52-3), the region is recognized as the safe region, and in a case where the OHT is located in a region between the third location information update device (51-3 or 52-3) and a fourth location information update device (51-4 or 52-4), the region is recognized as the danger region, and the location information is updated with the corresponding information.

Communication between the OHT controller (20) and the central controller (30) is performed for transmission and reception in both directions at the first frequency (F1 frequency), and the OHT controller (20) transmits location information, a travel speed, an OHT number, and OHT status (traveling/stopping) information to the central controller (30).

The central controller (30) transmits, to the OHT controller (20), the access permission status of the danger zone section for each track and the control status information for each OHT controller.

The central controller (30) transmits an access permission signal so that the OHT which first passes the first location information update device (51-1 or 52-1) and has started communication can first access the junction section.

Incidentally, the OHT having a travel speed of ‘0’ is considered in the stoppage and working (unloading/loading) and is excluded from access permission targets.

The central controller permits only one OHT to access the danger zone region.

The OHT controller (20) continues traveling and tries to access the junction in a case where the OHT controller receives permission for access from the central controller (30) before passing the second location information update device (51-2 or 52-2).

The OHT controller (20) which does not receive permission for access from the central controller (30) before passing the second location information update device (51-2 or 52-2) moves at a low speed and stops at the location of the third location information update device (51-3 or 52-3).

In a case where the central controller (30) determines that the location of the OHT passed the fourth location information update device (51-4 or 52-4), the central controller commands the OHT stopped at the location of the third location information update device (51-3 or 52-3) to first access the zone.

The central controller (30) commands the OHT which has first started communication to first access the zone in a case where there is no OHT stopped at the location of the third location information update device (51-3 or 52-3).

According to the invention, an existing power line communication system is capable of data processing only for a fixed device, but the invention has an advantage in that high-speed data processing can be performed for a device regardless of a fixed device or a moving device anywhere in a section where a power line is laid.

In addition, there is an existing RFID system in which a reader receives and processes information of a tag via near-field communication that enables communication with a moving object to be performed, but the RFID system has a low volume of data that can be stored in the tag and a low communication speed of about tens of Kbps, and thus it is difficult to transmit and process a large volume of data at a high speed. However, the invention has an advantage in that it is possible to perform high-speed communication which enables a large volume of data stored in a power line communication to be processed.

In addition, the invention has an advantage in that power supply and high-speed communication can be performed without separately laying a power supply and a communication cable in a termination/extension device of the system, thus having an advantage in that the termination/extension device can be easily extended.

Although the invention has been described in relation to the desired embodiments mentioned above, it is possible to make various modifications or alterations without departing from the gist and scope of the invention. Hence, the scope of the accompanying claims will include such modifications or alterations which pertains to the gist of the invention.

While the present invention has been described with respect to the specific embodiments, it will be apparent to those skilled in the art that various changes and modifications may be made without departing from the spirit and scope of the invention as defined in the following claims.

What is claimed is:

1. A junction passage control system based on a location of an OHT using a power line communication, comprising:
an OHT controller mounted on an OHT which moves along tracks; and a central controller that is installed in a junction section of the tracks and controls junction passing of a plurality of OHTs,
wherein power lines are laid on the tracks in a zone from a start point of the junction section to an end point of the junction section, and the central controller and the OHT controller transmit and receive data for a junction passage control through power line communication to and from each other.

2. The junction passage control system based on a location of an OHT using a power line communication according to claim 1,
wherein the central controller determines a location of a danger zone start point and a danger zone end point on each of the tracks of the junction section and, based on the determined locations, controls passage of the OHTs through the junction section.

3. The junction passage control system based on a location of an OHT using a power line communication according to claim 1,
wherein the OHT controller transmits, to the central controller through power line communication, OHT identification information and traveling information including at least one or more of OHT information indicating a traveling or stopping status, a travel distance, and a travel speed.

4. The junction passage control system based on a location of an OHT using a power line communication according to claim 1,
wherein the central controller transmits, to the OHT controller through the power line communication, data about the danger zone start point, information indicating whether access is permitted, the selected OHT identification information, and information of the number of OHT controllers in communication.

5. The junction passage control system based on a location of an OHT using a power line communication according to claim 1, further comprising:
a termination device that includes a transmission line matching unit for stable communication between the central controller and the OHT controller, the transmission line matching unit being installed at a terminal end of the power line, and that is coupled with the power line via a contact coupler to perform the power line communication with the central controller.

6. The junction passage control system based on a location of an OHT using a power line communication according to claim 1,
wherein the central controller is coupled with the power line via a contact coupler; and
the OHT controller is coupled with the power line via a non-contact coupler to perform the power line communication with the central controller.

7. The junction passage control system based on a location of an OHT using a power line communication according to claim 1,
wherein a junction section status display device that displays a status of the junction section is installed at the start point of to the junction section of the tracks; and
a camera is installed on each of the OHTs, and the OHT controller acquires access availability status information of the junction section from an image captured by the camera.

8. The junction passage control system based on a location of an OHT using a power line communication according to claim 1,
wherein each of the OHTs includes a sensor for detecting location movement information, and the OHT controller transmits the location movement information detected by the sensor to the central controller.

9. The junction passage control system based on a location of an OHT using a power line communication according to claim 8,
wherein the sensor is any one of an optical flow sensor, an IMU sensor, or a camera that detects a change on a surface of each of the tracks and recognizes a change of a location.

10. The junction passage control system based on a location of an OHT using a power line communication according to claim 1,
wherein a location information update device for detecting location movement information of the OHTs is installed on each of the tracks in the junction section, and the OHT controller receives the location movement information of the OHTs through a non-contact power line communication from the location information update device; and
a frequency of the non-contact power line communication is different from a frequency of communication between the central controller and the OHT controller.

11. The junction passage control system based on a location of an OHT using a power line communication according to claim 1,
wherein the power line is a two-wire transmission line and is laid so that a distance between two conductor lines is periodically variable; and
the OHT controller calculates a traveling location of each of the OHTs based on a reception intensity of a signal received through the power line.
